(19) United States
(12) Patent Application Publication
(10) Pub. No.: US 2016/0336172 A1
(43) Pub. Date: Nov. 17, 2016

(54) LITHOGRAPHY STACK AND METHOD

(71) Applicant: GLOBALFOUNDRIES Inc., Grand Cayman (KY)

(72) Inventors: Linus JANG, Clifton Park, NY (US); Sanggil BAE, Clifton Park, NY (US); Daeyoup LEE, Rexford, NY (US)

(73) Assignee: GLOBALFOUNDRIES INC., Grand Cayman (KY)

(21) Appl. No.: 14/712,197

(22) Filed: May 14, 2015

(51) Int. Cl. H01L 21/027; G03F 7/09; G03F 7/11; H01L 21/033; H01L 29/06

(52) U.S. Cl. CPC H01L 21/0273; H01L 21/0332; H01L 21/0337; H01L 29/0649; H01L 29/0692; G03F 7/11; G03F 7/091

(57) ABSTRACT

Lithography stack, intermediate semiconductor devices, and methods of fabrication are provided. The method includes obtaining an intermediate semiconductor device with a substrate, applying a spin on carbon layer over the substrate, and applying a hardmask layer over the spin on carbon layer. The intermediate semiconductor device includes a substrate, a spin on carbon layer over the substrate, and a hardmask layer over the spin on carbon layer. The lithography stack includes a spin on carbon layer, an invisible hardmask layer over the spin on carbon layer, and a photoresist layer over the invisible hardmask layer.

### FIELD OF THE INVENTION

The present invention relates to semiconductor devices and methods of fabricating semiconductor devices, and more particularly, to methods of forming lithography stacks during the lithography processes of fabrication, intermediate semiconductor devices with a lithography stack, and lithography stacks.

### BACKGROUND OF THE INVENTION

Semiconductor devices, such as integrated circuits, are typically fabricated using one or more lithography processes. The lithography processes are generally performed after application of a lithography stack over the semiconductor device. Many currently available lithography stacks may experience defects from rework which result in poor yield and advanced nodes may have high risks for defects that were not present in earlier nodes. In addition, currently available lithography stacks use materials that are chemically unstable or materials that require additional processing steps resulting in higher manufacturing costs.

### BRIEF SUMMARY

The shortcomings of the prior art are overcome and additional advantages are provided through the provision, in one aspect, of a method which includes, for instance: obtaining an intermediate semiconductor device with a substrate; applying a spin on carbon layer over the substrate; and applying a hardmask layer over the spin on carbon layer.

In another aspect, an intermediate semiconductor device is presented which includes, for instance: a substrate; a spin on carbon layer over the substrate; and a hardmask layer over the spin on carbon layer.

In yet another aspect, a lithography stack is presented which includes, for instance: a spin on carbon layer; an invisible hardmask layer over the spin on carbon layer; and a photoresist layer over the invisible hardmask layer.

Additional features and advantages are realized through the techniques of the present invention. Other embodiments and aspects of the invention are described in detail herein and are considered a part of the claimed invention.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 depicts a cross section of a portion of an intermediate semiconductor device, in accordance with one or more aspects of the present invention;

FIG. 2 depicts the intermediate semiconductor device of FIG. 1 with a spin on carbon layer deposited over the device, in accordance with one or more aspects of the present invention;

FIG. 3 depicts the intermediate semiconductor device of FIG. 2 with a hardmask layer applied over the spin on carbon layer, in accordance with one or more aspects of the present invention;

FIG. 4 depicts the intermediate semiconductor device of FIG. 3 with a photoresist layer applied over the hardmask layer, in accordance with one or more aspects of the present invention;

FIG. 5 depicts the intermediate semiconductor device of FIG. 4 after the photoresist layer has been patterned; and

FIG. 6 depicts one embodiment of a process for performing lithography on an intermediate semiconductor device, in accordance with one or more aspects of the present invention.

### DETAILED DESCRIPTION

Aspects of the present invention and certain features, advantages, and details thereof, are explained more fully below with reference to the non-limiting embodiments illustrated in the accompanying drawings. Descriptions of well-known materials, fabrication tools, processing techniques, etc., are omitted so as to not unnecessarily obscure the invention in detail. It should be understood, however, that the detailed description and the specific examples, while indicating embodiments of the invention, are given by way of illustration only, and are not by way of limitation. Various substitutions, modifications, additions and/or arrangements within the spirit and/or scope of the underlying inventive concepts will be apparent to those skilled in the art from this disclosure. Note also that reference is made below to the drawings, which are not drawn to scale for ease of understanding, wherein the same reference numbers used throughout different figures designate the same or similar components.

The present disclosure addresses and enhances, inter alia, lithography processing, more specifically, the lithography stack for use during semiconductor fabrication. Lithography processing typically includes applying a lithography stack over an intermediate semiconductor device which includes at least a substrate and may include additional fabrication topography. The lithography stacks have generally included at least a substrate and a photoresist layer applied over the substrate in order to transfer the pattern onto the substrate during lithography. As the size of technology nodes of semiconductor devices has decreased additional layers have been added to the lithography stack to account for substrate reflection and/or topography on the surface of the devices. For example, when the size of technology nodes decreased, devices started to experience defects due to substrate reflection created during the lithography processing. In order to account for the substrate reflection a bottom anti-reflection coating (BARC) layer was added between the substrate and photoresist layers.

As the size of the technology nodes continued to decrease and node technology advanced, the topography of some semiconductor devices changed and the topography of the semiconductor devices started to be negatively affected by the lithography processing. Devices may have added topography due to, for example, design specifications that result in raised features on the semiconductor devices, such as, fins, as well as other more complicated layering patterns. With the topography of semiconductor device designs becoming more important, the BARC layer was no longer able to account for the substrate reflection and the substrate topography. Thus, a planarization layer was added and applied over the substrate before application of the BARC layer. The planarization layer may account for the device topography to provide a planar surface for application of the BARC layer, whether or not the underlying topography is planar. The planarization layer may be, for example, a second BARC layer, and may have properties that enable it to be used for both planarization of the device and optimization of the substrate reflection. The BARC layer that is applied over the planarization layer may also serve as a hardmask layer for etching the planarization layer. In one embodiment, the second BARC layer is an organic material which is applied over the intermediate semiconductor device, then the first BARC layer which is an inorganic material is applied over the second BARC layer, and finally the photoresist layer, which is also an organic material, is applied over the first BARC layer to form a lithography stack. The inorganic first BARC layer is applied between the organic second BARC layer and organic photoresist layer to provide the selectivity necessary to transfer the photoresist pattern to the substrate. The first BARC layer being inorganic provides the necessary etch selectivity to enable the photoresist pattern to be transferred.

In one embodiment of a two BARC lithography stack, the lithography stack includes a first BARC layer that may be, for example, a silicon containing antireflection coating (SiARC) and a second BARC layer that may be, for example, an optical planarization layer (OPL). Thus, the lithography stack includes a substrate with an OPL layer applied over the substrate, then a SiARC layer applied over the OPL layer, and finally the photoresist layer applied over the SiARC layer. Since SiARC is chemically unstable, if rework is required due to overlay failures or the critical dimension not meeting the specifications, then the entire lithography stack must be removed and reapplied. In addition, SiARC can cause defects in the resulting semiconductor devices if rework is performed due to failure to remove all the silicon particles from the substrate. If additional silicon particles remain on the substrate after rework they will cause defects and be a yield detractor in the resulting semiconductor device.

Generally stated, disclosed herein are certain novel lithography processing methods and lithography stacks, which provide significant advantages over the above noted, existing lithography processing methods and lithography stacks. Advantageously, the lithography processing methods and lithography stacks disclosed herein may prevent defects and improve the yield of resulting semiconductor devices. Additionally, as explained herein, the lithography processing methods and lithography stacks disclosed herein may reduce production costs by decreasing the number of materials needed in the lithography stack and reducing the materials which need to be removed and reapplied during rework. By reducing the number of materials used and the number of reworks, the number of etch processes is also reduced which in turn may reduce process variation to lower the rework rate and result in lower cost and better yield.

During fabrication a substrate or wafer will be processed through numerous procedures to create the semiconductor device. One such procedure is lithography processing of the substrate. In order for the substrate to undergo lithography processing, a lithograph stack must be applied over the substrate.

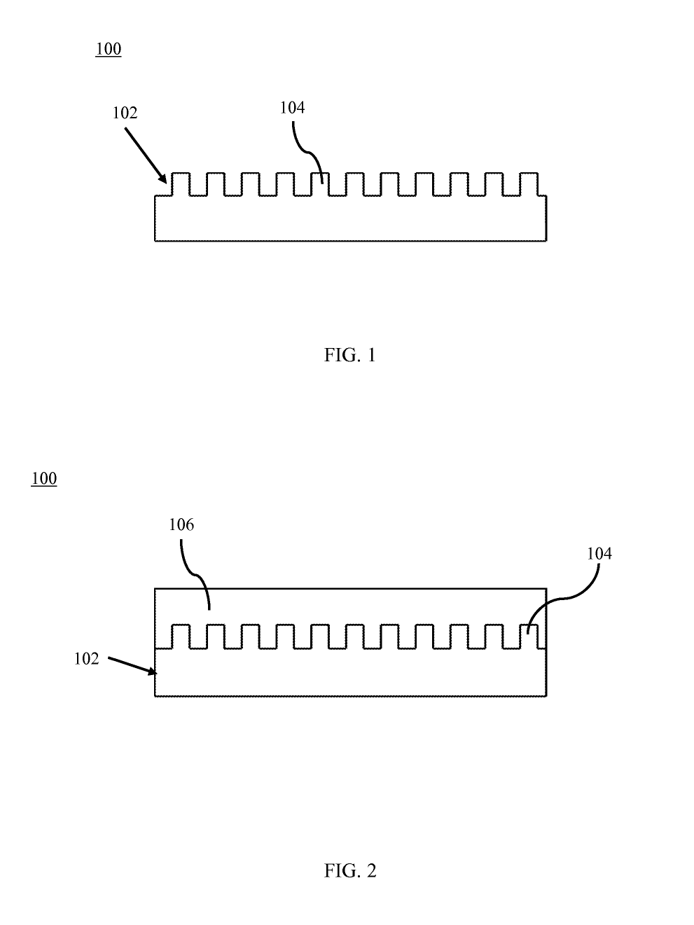

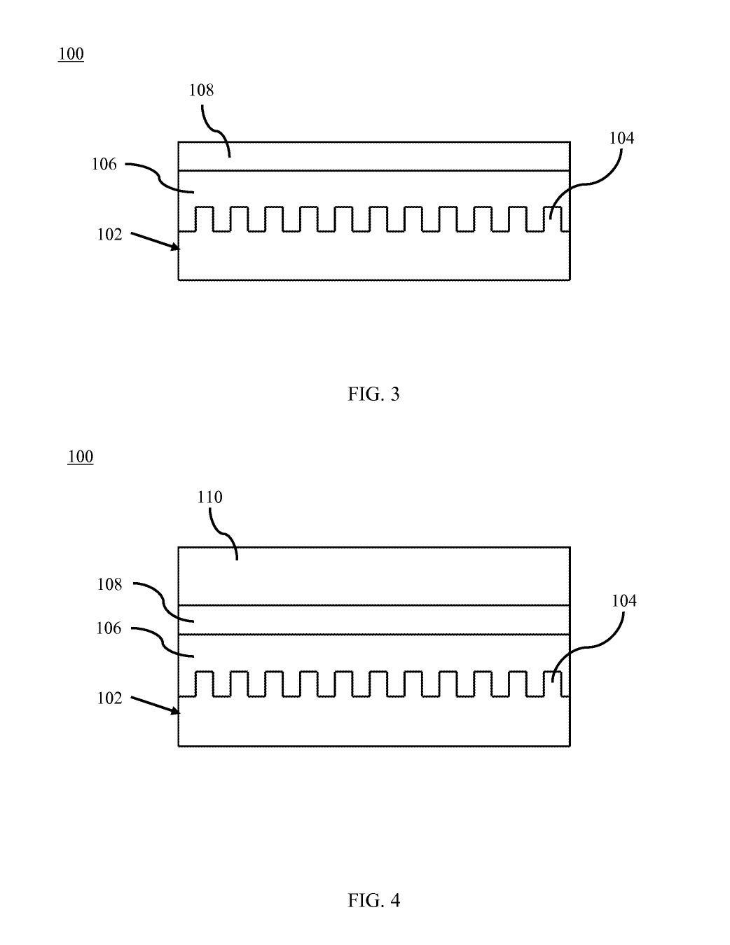

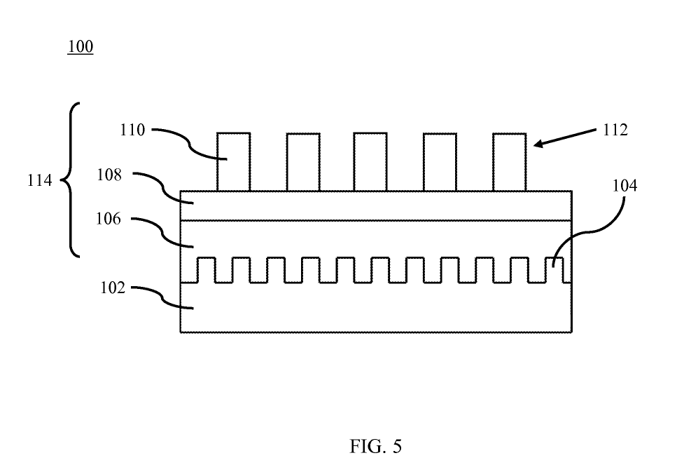

As shown in FIGS. 1-5, a lithography stack 114 is formed by the application of multiple layers over a substrate 102. Referring now to FIG. 1, a portion of an integrated circuit 100 including a substrate 102 is shown. The substrate 102 may include, for example, at least one raised structure 104 extending out from the substrate 102. The at least one raised structure 104 may be, for example, a FinFET, layer pattern, or other design specification that results in formation of at least one raised structure 104 on the substrate 102. As shown in FIG. 2, the integrated circuit 100 may also include an organic layer 106, for example, a SOC layer, over the substrate 102. The SOC layer 106 may include, for example, both a BARC material and OPL material or alternatively a single material for both reflection control and planarization. The organic layer 106 may be applied by, for example, spin-coating or casting. The integrated circuit 100 may also include a hardmask layer 108, as depicted in FIG. 3, over the SOC layer 106. The hardmask layer 108 may be, for example, an invisible hardmask layer, such as, PVD SiOₓN_{y}. The hardmask layer 108 may be applied by, for example, physical vapor deposition (PVD). The PVD SiOₓN_{y} films may be applied to the integrated circuit 100 without hydrogen, unlike CVD SiOₓN_{y} which requires the use of hydrogen for deposition. The integrated circuit 100 may also include a photoresist layer 110 over the hardmask layer 108, as shown in FIG. 4. Finally, as illustrated in FIG. 5, the integrated circuit 100 may have a photoresist layer 110 which is patterned to form a photoresist pattern 112. The SOC layer 106, hardmask layer 108, and the photoresist pattern 112 may form a lithography stack 114. The lithography stack 114 may then be used to perform lithography processing.

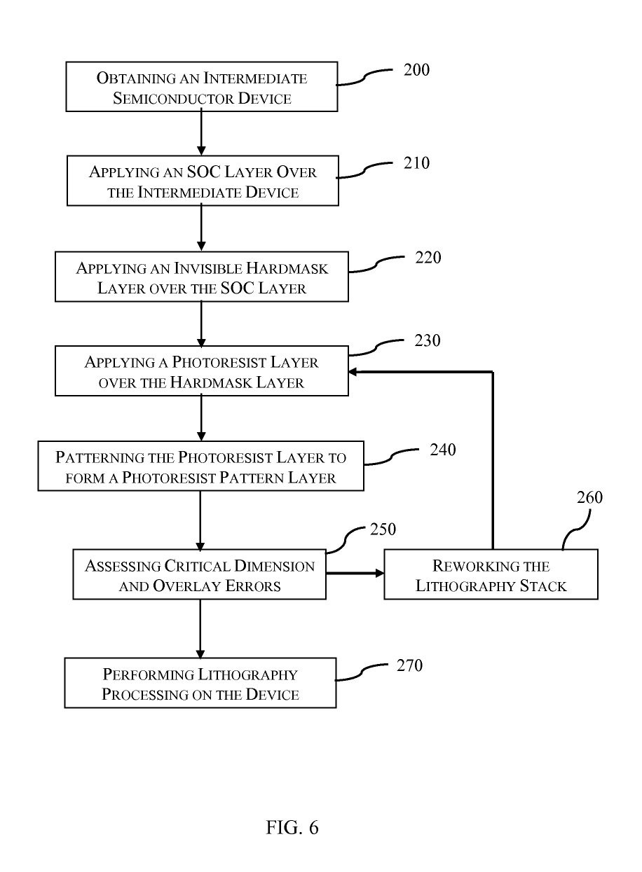

In one aspect, in one embodiment, as shown in FIG. 6, a portion of the semiconductor device fabrication process in accordance with one or more aspects of the present invention may include, obtaining an intermediate semiconductor device 200, applying a SOC layer over the intermediate semiconductor device 210, applying an invisible hardmask layer over the SOC layer 220, applying a photoresist layer over the invisible hardmask layer 230, patterning the photoresist layer to form a photoresist pattern layer 240, and performing lithography processing 270. The semiconductor fabrication process may also include, for example, assessing the device for critical dimension and overlay errors 250. If there are overlay failures or the critical dimensions are not meeting the specifications, then the fabrication process may further include reworking the lithography stack 260. Reworking the lithography stack 260 may include removing the photoresist layer and then passing the device to have a new photoresist layer applied 230. Once a new photoresist layer is applied the device may then move to patterning to form a photoresist pattern layer 240 and the reworked device will then be passed to have the critical dimensions and overlay assessed 250. If the critical dimensions and overlay once again do not meet the specifications the device will again be passed for rework 260. However, if the critical dimensions and overlay meet the device specifications, the device will be passed to have lithography processing performed 270. The lithography processing 270 may include, for example, transferring a photoresist pattern to the photoresist layer, hardmask layer, and SOC layer, imaging the photoresist pattern, and transferring the pattern to the substrate.

With continued reference to the fabrication processes of FIG. 6 and the lithography stack of FIG. 5, the intermediate semiconductor devices, such as, device 100 may include a substrate 102 that includes at least one raised structure 104. The SOC layer 106 is applied over the substrate 102 and may provide for both reflection control for the lithography stack 114 and planarization of the substrate 102 to provide a planar surface for the application of the hardmask layer 108 when needed. The SOC layer 106 may include, for example, a BARC material and an OPL material or alternatively a single material having the properties of both a BARC material and an OPL material. The material of the SOC layer 106 includes a refractive index (n) value and an extinction coefficient (k) value. The values of the refractive index and extinction coefficient of the SOC layer 106 may be tuned to minimize the reflectivity of the substrate 102, as described in greater detail below.

The invisible hardmask layer 108 is applied over the SOC layer 104 and acts as a capping layer to allow for the photoresist layer 110 to be removed without removing the entire lithography stack 114. The invisible hardmask layer 108 is invisible to the imager at the imaging wavelength, which may be, for example, 193 nm. Thus, if rework is required on a semiconductor device 100 with a lithography stack 114 the rework path will be cleaner because only the organic photoresist layer 110 will need to be removed and reapplied. The material of the hardmask layer 108 may include optical properties that include a refractive index (n) value and an extinction coefficient (k) value. The values of the refractive index (n) and extinction coefficient (k) of the hardmask layer 108 may be adjusted to match the refractive index (n) and extinction coefficient (k) values of the photoresist layer 110 at the imaging wavelength. When the refractive index (n) and extinction coefficient (k) values of the hardmask layer 108 match the n and k values of the photoresist 110 at the imaging wavelength the hardmask layer 108 is invisible to the imager. The hardmask layer 108 may be, for example, physical vapor deposition (PVD) SiOₓN_{y}. The PVD SiOₓN_{y} may be applied without hydrogen, thus, enabling a lower extinction coefficient (k) value for the hardmask layer 108 that cannot be achieved when using chemical vapor deposition to apply SiOₓN_{y}. Thus, using PVD SiOₓN_{y} enables the extinction coefficient (k) of the hardmask layer 108 to be matched to the extinction coefficient (k) of the photoresist layer. Alternative deposition processes, for example, spin coating and the like, that maintain the optical properties of the hardmask layer 108 and are able to match the optical properties of the hardmask layer 108 to the photoresist layer 110 are also contemplated. Since PVD can be performed without hydrogen, this enables deposition of a SiOₓN_{y} hardmask with a refractive index (n) and extinction coefficient (k) matched to the photoresist layer 110. A SiOₓN_{y} hardmask layer 108 allows for direct etching on the SiOₓN_{y} layer which enables process induced variations to be minimized providing better process control which reduces the need for rework and therefore reduces defects which lowers costs and produces higher yield. In addition, the hardmask layer 108 provides a chemically stable inorganic base for the photoresist layer 110 to be applied. The chemically stable inorganic hardmask layer 108 prevents scumming or poisoning, thus, the resultant semiconductor devices may have improved critical dimension uniformity, improved line edge roughness, and improved line width roughness.

By way of specific example only, one detailed embodiment of the lithography stack may include, for example, a substrate 102, at least one raised structure 104 on the substrate 102, a SOC layer 106 over the substrate 102, an invisible hardmask layer 108 over the SOC layer 106, a photoresist layer 110 over the invisible hardmask layer 108, and an optional top coat (not shown) over the photoresist layer 110. The substrate 102 may have refractive index (n) and extinction coefficient (k) values of, for example, approximately 0.88 and 2.78. The at least one raised structure 104 may be for example, TiN which may have n and k values of, for example, approximately 2.10 and 1.51. The SOC layer 106 may have n and k values of, for example, approximately 1.60 and 0.35. The invisible hardmask layer and the photoresist layer may each have n and k values of, for example, approximately 1.68 and 0.03. Finally, the topcoat (not shown) may have n and k values of, for example, approximately 1.54 and 0.006. The refractive index (n) and extinction coefficient (k) values will be dependent on the materials being used for each layer.

The lithography stack 114 and method of forming the lithography stack 114 as described in greater detail above may, for example, reduce rework costs because only the photoresist layer 110 needs to be removed and reapplied if there are overlay failures or the critical dimensions do not meeting the specifications of the semiconductor device. In addition, since only the organic photoresist layer 110 needs to be removed and reapplied the opportunities for defect creation are decreased compared to those seen with other lithography stacks and methods. The lithography stack 114 may be used, for example, for single patterning or multiple patterning and may also be used on any size technology node. The lithography stack 114 may also simplify patterning and reduce process variation because there are less layers and steps in forming the lithography stack 114 and patterning after etching. With the decrease in defects caused by rework when using the lithography stack 114, the yield of the resultant semiconductor device may be enhanced.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

1. A method, comprising:
obtaining an intermediate semiconductor device, the device including a substrate;
applying a spin on carbon layer over the substrate;
applying a hardmask layer over the spin on carbon layer;
applying a photoresist layer over the hardmask layer;
patterning the photoresist layer to form a photoresist pattern layer; and
assessing the photoresist pattern layer for critical dimension and overlay errors, if there are critical dimension and overlay errors removing the photoresist layer and applying a new photoresist layer over the hardmask layer.

2. The method of claim 1, further comprising:
performing lithography on the intermediate semiconductor device when there are no critical dimension and overlay errors.

3. The method of claim 1, wherein the substrate comprises:
a top surface; and
at least one raised structure extending above the top surface.

4. The method of claim 1, wherein the spin on carbon layer comprises:
a bottom anti-reflection coating material; and
an optical planarization layer.

5. The method of claim 2, wherein the hardmask layer is a physical vapor deposition silicon oxynitride material.

6. The method of claim 5, wherein the physical vapor deposition silicon oxynitride material has a refractive index and an extinction coefficient that is matched to a refractive index and an extinction coefficient of the photoresist layer.

7. The method of claim 2, wherein the spin on carbon layer comprises a refractive index and an extinction coefficient.

8. The method of claim 7, further comprising:
adjusting the refractive index and extinction coefficient of the spin on carbon layer to minimize the reflectivity of the substrate.

9. An intermediate semiconductor device comprising:
a substrate;
a spin on carbon layer over the substrate; and
a hardmask layer over the spin on carbon layer.

10. The device of claim 9, further comprising:
a photoresist layer over the hardmask layer.

11. The device of claim 10, wherein the substrate comprises:
a top surface; and
at least one raised structure extending above the top surface.

12. The device of claim 10, wherein the spin on carbon layer comprises:
a bottom anti-reflection coating material; and
an optical planarization layer.

13. The device of claim 12, wherein the spin on carbon layer comprises:
a refractive index; and
an extinction coefficient.

14. The device of claim 13, wherein the hardmask layer is a silicon oxynitride material.

15. The device of claim 14, wherein the silicon oxynitride material has a refractive index and an extinction coefficient that match a refractive index and an extinction coefficient of the photoresist layer.

16. A lithography stack, comprising:
an organic layer;
an invisible hardmask layer over the organic layer; and
a photoresist layer over the invisible hardmask layer.

17. The lithography stack of claim 16, wherein the organic layer comprises:
a bottom anti-reflection coating material; and
an optical planarization layer.

18. The lithography stack of claim 16, wherein the photoresist layer comprises:
a refractive index; and
an extinction coefficient.

19. The lithography stack of claim 18, wherein the hardmask layer comprises:
a refractive index; and
an extinction coefficient.

20. The lithography stack of claim 19, wherein the refractive index and the extinction coefficient of the hardmask layer are equal to the refractive index and the extinction coefficient of the photoresist layer.
